(19) United States
(12) Patent Application Publication
(10) Pub. No.: US 2025/0022854 A1
(43) Pub. Date: Jan. 16, 2025

(54) MICRO LIGHT-EMITTING DIODE PACKAGE

(71) Applicant: Lextar Electronics Corporation, Hsinchu City (TW)

(72) Inventors: Chih-Hao LIN, Hsinchu City (TW); Po-Han WU, Hsinchu City (TW); Tsung-Hao SU, Hsinchu City (TW); Wei-Yuan MA, Hsinchu City (TW)

(21) Appl. No.: 18/747,368

(22) Filed: Jun. 18, 2024

(30) Foreign Application Priority Data
Jul. 13, 2023 (TW) 112126148

(51) Int. Cl. H01L 25/075

(52) U.S. Cl. CPC H01L 25/0753

(57) ABSTRACT

Provide a micro-light-emitting package includes a first substrate, a plurality of micro-light-emitting diodes (micro-LEDs), a transparent protective layer, and a plurality of conductive pads. The first substrate has an upper surface and a lower surface opposite to each other. The micro-LEDs are disposed on the upper surface of the first substrate. The micro-LEDs have a first electrode and a second electrode electrically opposite to the first electrode. The transparent protective layer covers the micro-LEDs. The plurality of conductive pads are disposed on the lower surface of the first substrate. The conductive pads include a first conductive pad, a second conductive pad, a third conductive pad, and a fourth conductive pad. The first conductive pad, the second conductive pad, the third conductive pad respectively electrically connected to the corresponding first electrode of the micro-LEDs. The fourth conductive pad is commonly electrically connected to the second electrode of the plurality of micro-LEDs.

### CROSS REFERENCE TO RELATED APPLICATIONS

This application claims priority of Taiwan Patent Application No. 112126148, filed on Jul. 13, 2023, and the content of the entirety of which is incorporated by reference herein.

### Technical Field

The present disclosure relates to a micro-LED package, and in particular to a micro-LED package for fluid assembly.

### BACKGROUND

### Description of the Related Art

Micro light-emitting diode (micro-LED) displays use micro-LEDs to emit three colors of light: red light, green light, and blue light. The challenge with micro-LED displays is to precisely place millions of micro-LEDs in the correct locations on a display substrate to connect circuits and form pixel arrays. The micro-LEDs are grabbed from the supply substrate of the micro-light-emitting diodes by stamping, and then the micro-light-emitting diodes are placed on the display substrate. Transfer time can take days for high-definition televisions (HDTV) with 6.2 million sub-pixels and a pitch of 200 micrometers (m). For 4K and 8K TVs, the number of sub-pixels increases to 24.9 million and 99.5 million respectively, while the sub-pixel size decreases accordingly, and thus the complexity and cost of the above technology rises significantly as the pixel density increases.

### SUMMARY

Some embodiments of the present disclosure provide a micro-LED package. The micro-LED package includes a first substrate, a plurality of micro-LED chips, a transparent protective layer, and a plurality of conductive pads. The first substrate has an upper surface and a lower surface opposite to each other. The micro-LED chip is disposed on the upper surface of the first substrate, wherein the micro-LED chip has a first electrode and a second electrode that is electrically opposite to the first electrode. The transparent protective layer covers the micro-LED chips. The plurality of conductive pads are disposed on the lower surface of the first substrate, and the conductive pads include a first conductive pad, a second conductive pad, a third conductive pad, and a fourth conductive pad. The first conductive pad, the second conductive pad, and the third conductive pad is electrically connected to the first electrode of the corresponding one of the micro-LED chips respectively, and the fourth conductive pad is electrically connected to each of the second electrodes of the plurality of micro-LED chips.

The foregoing does not represent every embodiment or aspect of the present disclosure but merely provides examples of some of the novel aspects and features described herein. The above-mentioned features and advantages, as well as other features and advantages of the disclosure, will become apparent from the following detailed description of representative embodiments and methods of implementing the disclosure when combined with the accompanying drawings and appended claims.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion.

FIG. 1 is a schematic cross-sectional view of a micro-LED package according to some embodiments of the present disclosure.

FIG. 2 is a bottom view of a micro-LED package according to some embodiments of the present disclosure.

FIG. 3 is a top view of a second substrate of the micro-LED package according to some embodiments of the present disclosure.

FIG. 4 is a schematic cross-sectional view of a micro-LED package mounted on a second substrate according to some embodiments of the present disclosure.

FIG. 5A is a schematic cross-sectional view of a micro-LED package that is not mounted on a second substrate according to some embodiments of the present disclosure.

FIG. 5B is a top view of a micro-LED package that is not mounted on a second substrate according to some embodiments of the present disclosure.

FIG. 6 is a schematic diagram of the circuit routings of the first substrate of the micro-LED package according to some embodiments of the present disclosure.

FIG. 7 is a bottom view of a micro-LED package according to some embodiments of the present disclosure.

FIG. 8 is a bottom view of a micro-LED package according to some embodiments of the present disclosure.

FIG. 9 is a top view of a second substrate according to some embodiments of the present disclosure.

FIG. 10 is a top view of a second substrate according to some embodiments of the present disclosure.

FIG. 11 is a top view of a second substrate according to some embodiments of the present disclosure.

FIG. 12 is a schematic diagram of the circuit routings of the first substrate of the micro-LED package according to some embodiments of the present disclosure.

FIG. 13 is a schematic cross-sectional view of a micro-LED package mounted on a second substrate according to some embodiments of the present disclosure.

FIG. 14 is a bottom view of a micro-LED package according to some embodiments of the present disclosure.

FIG. 15 is a bottom view of a micro-LED package according to some embodiments of the present disclosure.

FIG. 16 is a top view of the second substrate according to some embodiments of the present disclosure.

FIG. 17 is a top view of a second substrate according to some embodiments of the present disclosure.

FIG. 18 is a top view of the second substrate according to some embodiments of the present disclosure.

FIG. 19 is a schematic diagram of the circuit routings of the first substrate of the micro-LED package according to some embodiments of the present disclosure.

FIG. 20 is a schematic cross-sectional view of a micro-LED package mounted on a second substrate according to some embodiments of the present disclosure.

FIG. 21 is a bottom view of a micro-LED package according to some embodiments of the present disclosure.

FIG. 22 is a top view of the second substrate according to some embodiments of the present disclosure.

FIG. 23 is a schematic diagram of the circuit routings of the first substrate of the micro-LED package according to some embodiments of the present disclosure.

FIG. 24 is a schematic cross-sectional view of the micro-LED package mounted on the second substrate taken along line A-A′ in FIG. 22.

FIG. 25 is a schematic cross-sectional view of a micro-LED package according to some embodiments of the present disclosure.

FIG. 26 is a schematic cross-sectional view of a micro-LED package according to some embodiments of the present disclosure.

FIG. 27 shows the situation of micro-LED packages in fluid assembly according to some embodiments of the present disclosure.

FIG. 28 shows the situation of micro-LED packages in fluid assembly according to some embodiments of the present disclosure.

FIG. 29 shows the situation of the micro-LED package of Comparative Embodiment 1 in the fluid assembly according to some embodiments of the present disclosure.

FIG. 30 shows the upper surfaces of the blue micro-LED chip and the green micro-LED chip according to the present disclosure.

### DETAILED DESCRIPTION

The following disclosure provides many different embodiments, or examples, for implementing different features of the provided quantum dot composite structures. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat symbols and/or characters of components in different embodiments or examples. This repetition is for simplicity and clarity, rather than to represent the relationship between the different embodiments and/or examples discussed.

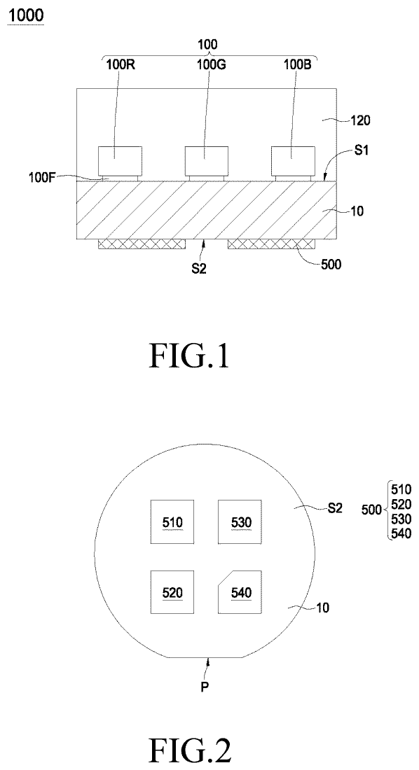

The present disclosure provides a micro-LED (micro-LED) package. Please refer to FIG. 1. FIG. 1 is a schematic cross-sectional view of a micro-LED package according to some embodiments of the present disclosure.

Referring to FIG. 1, a micro-LED package 1000 includes a first substrate 10, a plurality of micro-LED chips 100, a transparent protective layer 120, and a plurality of conductive pads 500. The first substrate 10 has an upper surface S1 and a lower surface S2 opposite to each other. The micro-LED chip 100 is disposed on the upper surface S1 of the first substrate 10, wherein the micro-LED chip 100 has a first electrode 100F and a second electrode 100S (not shown) that is electrically opposite to the first electrode 100F. The transparent protective layer 120 covers the micro-LED chip 100. A plurality of conductive pads 500 is disposed on the lower surface S2 of the first substrate 10. Referring to FIG. 2, a conductive pad 500 includes a first conductive pad 510, a second conductive pad 520, a third conductive pad 530, and a fourth conductive pad 540. Through the circuit routings (not shown) in the first substrate 10, each of the first conductive pad 510, the second conductive pad 520, and the third conductive pad 530 is electrically connected to the first electrode 100F of the corresponding one of the micro-LED chips 100 respectively, and the fourth conductive pad 540 is electrically connected to each of the second electrodes 100S of the plurality of micro-LED chips 100 (not shown). That is, the first substrate 10 is provided with a circuit routing layout for electrically connecting the micro-LED chips 100 and the first substrate 10.

In some embodiments, the micro-LED chip 100 may be a micro-LED chip or a quantum dot LED, but the present disclosure is not limited thereto. In some embodiments, the micro-LED chip 100 can emit red light, green light, or blue light, but the present disclosure is not limited thereto. The micro-LED chip 100 can also emit light of other wavelengths, such as ultraviolet light (UV). In some embodiments, the micro-LED chip 100 may be a flip-chip LED chip.

Referring to FIG. 1, in some embodiments, the micro-LED chip 100 includes a red micro-LED chip 100R, a blue micro-LED chip 100B, and a green micro-LED chip 100G.

In some embodiments, the red micro-LED chip 100R has a first electrode 100R1, and a second electrode 100R2. The blue micro-LED chip 100B has a first electrode 100B1 and a second electrode 100B2. The green micro-LED chip 100G has a first electrode 100G1 and a second electrode 100G2.

In some embodiments, the first electrode 100F includes the first electrode 100B1 of the blue micro-LED chip 100B, the first electrode 100G1 of the green micro-LED chip 100G, and the first electrode 100R1 of the red micro-LED chip 100R, while the second electrode 100S includes the second electrode 100B2 of the blue micro-LED chip 100B, the second electrode 100G2 of the green micro-LED chip 100G, and the second electrode 100R2 of the red micro-LED chip 100R.

In some embodiments, the first electrode 100B1 of the blue micro-LED chip 100B, the first electrode 100G1 of the green micro-LED chip 100G, and the first electrode 100R1 of the red micro-LED chip 100R are positive electrodes, while the second electrode 100B2 of the blue micro-LED chip 100B, the second electrode 100G2 of the green micro-LED chip 100G, and the second electrode 100R2 of the red micro-LED chip 100R are negative electrodes.

In some embodiments, the first electrode 100B1 of the blue micro-LED chip 100B, the first electrode 100G1 of the green micro-LED chip 100G, and the first electrode 100R1 of the red micro-LED chip 100R are negative electrodes, while the second electrode 100B2 of the blue micro-LED chip 100B, the second electrode 100G2 of the green micro-LED chip 100G, and the second electrode 100R2 of the red micro-LED chip 100R are positive electrodes.

In some embodiments, the transparent protective layer 120 may include solid molding material (e.g., epoxy molding compound (EMC)), silicone resin (e.g., polysiloxane or silicone), liquid molding compound (LMC), but the present disclosure is not limited thereto, and other suitable molding materials are also applicable to the present disclosure. In some embodiments, the light transmittance of the transparent protective layer 120 may be greater than 90%. In some embodiments, the thickness of the transparent protective layer 120 is in a range from 20 microns to 90 microns, such as 20 microns, 30 microns, 40 microns, 50 microns, 60 microns, 70 microns, 80 microns, or 90 microns.

Referring to FIG. 2, in some embodiments, when viewed from a bottom view of the micro-LED package 1000, the first substrate 10 of the micro-LED package 1000 has a flat edge P. Therefore, the shape of the micro-LED package 1000 in a top view is similar to a silicon wafer shape with flat edges, that is, a circular shape with the flat edge P.

Referring to FIG. 1 and FIG. 2, in the bottom view of the micro-LED package 1000, a plurality of conductive pads 500 are disposed on the lower surface S2 of the first substrate 10, and the conductive pads 500 include a first conductive pad 510, a second conductive pad 520, a third conductive pad 530, and a fourth conductive pad 540.

In some embodiments, the lower surfaces of the first conductive pad 510, the second conductive pad 520, the third conductive pad 530, and the fourth conductive pad 540 may be substantially level, but the present disclosure is not limited thereto. In some embodiments, the thicknesses of the first conductive pad 510, the second conductive pad 520, the third conductive pad 530, and the fourth conductive pad 540 may be substantially the same. In some embodiments, the thickness of the first conductive pad 510, the thickness of the second conductive pad 520, and the thickness of the third conductive pad 530 are greater than the thickness of the fourth conductive pad 540. In some embodiments, the thickness of the first conductive pad 510, the thickness of the second conductive pad 520, and the thickness of the third conductive pad 530 are less than the thickness of the fourth conductive pad 540. In some embodiments, the thicknesses of the first conductive pad 510, the second conductive pad 520, the third conductive pad 530, and the fourth conductive pad 540 are different.

In some embodiments, the shapes of the lower surfaces of the first conductive pad 510, the second conductive pad 520, the third conductive pad 530, and the fourth conductive pad 540 may be polygonal. In some embodiments, the shapes of the lower surfaces of the first conductive pad 510, the second conductive pad 520, the third conductive pad 530, and the fourth conductive pad 540 may be heptagonal, hexagonal, pentagonal, rectangular, or triangular, but the present disclosure is not limited thereto. In some embodiments, the shapes of the lower surfaces of the first conductive pad 510, the second conductive pad 520, the third conductive pad 530, and the fourth conductive pad 540 may be oval or circular, but the present disclosure is not limited thereto.

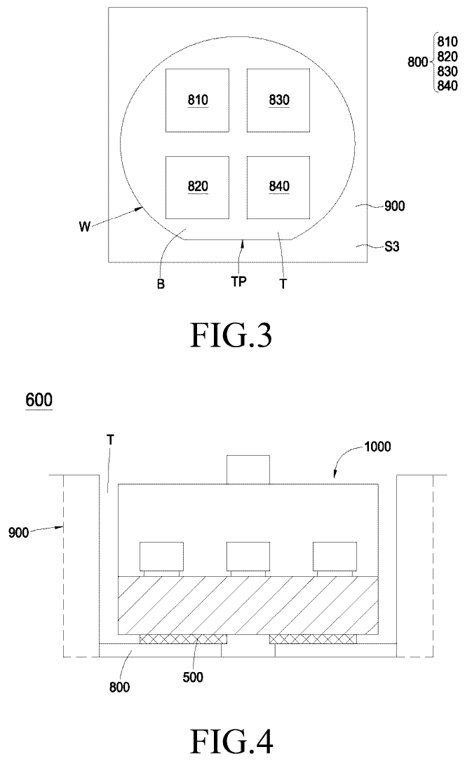

Referring to FIG. 3, FIG. 3 is a top view of the second substrate 900 according to some embodiments of the present disclosure. The second substrate 900 has an upper surface S3 and an accommodating groove T, the accommodating groove T has a side wall W, and a plurality of conductive junctions 800 are provided on the bottom surface B of the accommodating groove T, wherein the accommodating groove T is shaped like a silicon wafer (with flat-cut edges). The conductive junction 800 includes a first conductive junction 810, a second conductive junction 820, a third conductive junction 830, and a fourth conductive junction 840. The first conductive junction 810, the second conductive junction 820, the third conductive junction 830, and the fourth conductive junction 840 are disposed on the bottom surface B of the accommodating groove T. The second substrate 900 has a flat edge protrusion TP extending from the side wall W of the accommodating groove T. The flat edge P is substantially matched with the flat edge protrusion TP in shape.

Referring to FIG. 3, although FIG. 3 only shows that the second substrate 900 has one accommodating groove T, the number of the accommodating groove T is not limited thereto. In some embodiments, the second substrate 900 includes a plurality of accommodating groove T. Thus, the efficiency of the overall fluid assembly is increased.

FIG. 4 is a schematic cross-sectional view of a micro-LED package mounted on a second substrate 900 according to some embodiments of the present disclosure. Referring to FIG. 4, in some embodiments, through fluid assembly, the micro-LED package 1000 is disposed in the accommodating groove T, and the flat edge protrusion TP of the second substrate 900 corresponds to the flat edge P of the first substrate 10 of the micro-LED package 1000. In some embodiments, the flat edge protrusion TP of the second substrate 900 is substantially matched with the flat edge P of the first substrate 10 in shape. During fluid assembly, when the micro-LED package 1000 is disposed in the accommodating groove T of the second substrate 900, only when the flat edge protrusion TP of the second substrate 900 is aligned with the flat edge P of the first substrate 10 will the micro-LED package 1000 be disposed in the accommodating groove T, and ensure that the conductive pad 500 of the micro-LED package 1000 is connected to the conductive junction 800. That is, each of the first conductive pad 510, the second conductive pad 520, the third conductive pad 530, and the fourth conductive pad 540 of the micro-LED package 1000 are respectively connected in the correct direction and the correct polarity with each of the first conductive junction 810, the second conductive junction 820, the third conductive junction 830 and the fourth conductive junction 840. In some embodiments, each of the micro-LED packages 1000 mounted to each of the accommodating grooves T of the second substrate 900 to form a micro-LED display device 600.

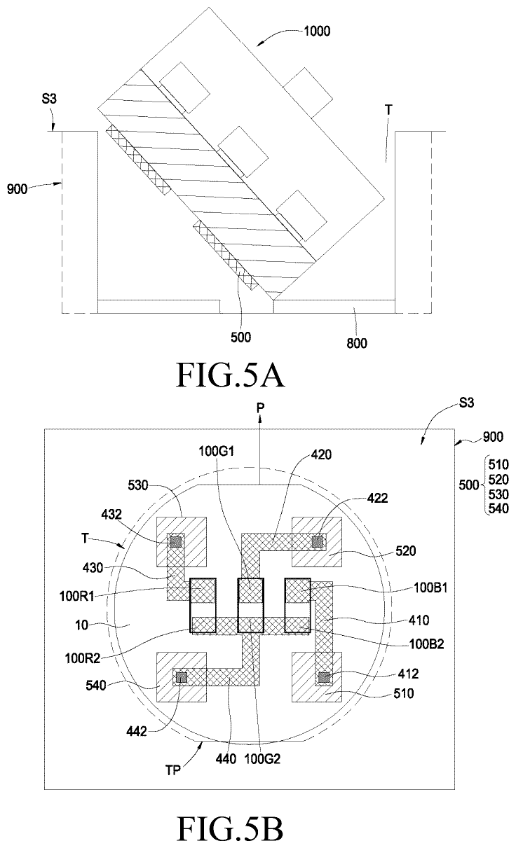

FIG. 5A is a schematic cross-sectional view of a micro-LED package that is not mounted on a second substrate according to some embodiments of the present disclosure. Referring to FIG. 5A, in some embodiments, when the flat edge protrusion TP of the second substrate 900 is not aligned with the flat edge P of the first substrate 10 during fluid assembly, the micro-LED package 1000 will not be able to be disposed in the accommodating groove T. In some embodiments, if the conductive pad 500 of the micro-LED package 1000 faces the accommodating groove T, but if the flat edge P of the micro-LED package 1000 is not aligned with the second substrate 900, the micro-LED package 1000 will not be able to be disposed in the accommodating groove T. At this time, the micro-LED package 1000 will be driven by the suspended fluid to leave the accommodating groove T, and will continue to roll on the upper surface S3 of the second substrate 900, then may fall into another accommodating groove T (as shown in FIG. 4).

FIG. 5B is a top view of a micro-LED package that is not mounted on a second substrate according to some embodiments of the present disclosure. In some embodiments, when the flat edge protrusion TP of the second substrate 900 is not aligned with the flat edge P of the first substrate 10 during fluid assembly, the micro-LED package 1000 will not be able to be disposed in the accommodating groove T. The micro-LED package 1000 needs to be rotated 180 degrees before it can be disposed in the accommodating groove T.

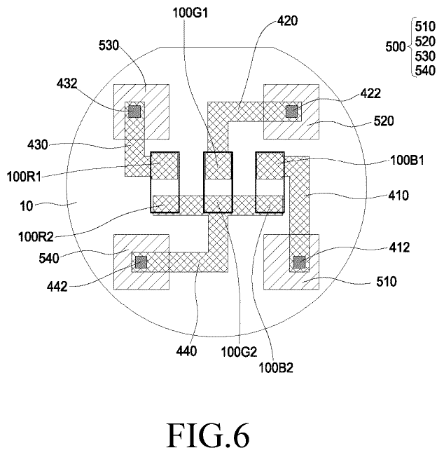

FIG. 6 is a schematic diagram of the circuit routings of the first substrate 10 of the micro-LED package 1000 according to some embodiments of the present disclosure. FIG. 6 is a schematic diagram of the circuit routings of the first substrate 10 of the micro-LED package 1000 in FIG. 2. In some embodiments, the micro-LED chip 100 may be a flip-chip LED chip. The first electrode 100B1 of the blue micro-LED chip 100B is electrically connected to the conductive circuit 410, and the conductive circuit 410 is electrically connected to the via 412, which passes through the first substrate 10 from the upper surface S1 of the first substrate 10 to the lower surface S2 and is electrically connected to the first conductive pad 510 on the lower surface S2. The first electrode 100G1 of the green micro-LED chip 100G is electrically connected to the conductive circuit 420, and the conductive circuit 420 is electrically connected to the via 422, which passes through the first substrate 10 from the upper surface S1 of the first substrate 10 to the lower surface S2 and is electrically connected to the second conductive pad 520 on the lower surface S2. The first electrode 100R1 of the red micro-LED chip 100R is electrically connected to the conductive circuit 430, and the conductive circuit 430 is electrically connected to the via 432, which passes through the first substrate 10 from the upper surface S1 of the first substrate 10 to the lower surface S2 and is electrically connected to the third conductive pad 530 on the lower surface S2. Furthermore, the second electrode 100B2 of the blue micro-LED chip 100B, the second electrode 100G2 of the green micro-LED chip 100G, and the second electrode 100R2 of the red micro-LED chip 100R are electrically connected to the conductive circuit 440, and the conductive circuit 440 is electrically connected to the via 442, which passes through the first substrate 10 from the upper surface S1 of the first substrate 10 to the lower surface S2 and is electrically connected to the fourth conductive pad 540 on the lower surface S2.

In some embodiments, the conductive circuit 410, the conductive circuit 420, the conductive circuit 430, and the conductive circuit 440 are flatly arranged on the upper surface S1 of the first substrate 10. The conductive circuits 410, 420, and 430 are L-shaped. In some embodiments, the conductive circuit 440 is J-shaped. In some embodiments, the first conductive pad 510, the second conductive pad 520, the third conductive pad 530, and the fourth conductive pad 540 are flatly arranged on the lower surface S2 of the first substrate 10. In some embodiments, the first conductive pad 510, the second conductive pad 520, the third conductive pad 530, and the fourth conductive pad 540 are square.

Through the structural design of the circuit routings described above, the first conductive pad 510 is electrically connected to the first electrode 100B1 of the blue micro-LED chip 100B, and the second conductive pad 520 is electrically connected to the first electrode 100G1 of the green micro-LED chip 100G. The third conductive pad 530 is electrically connected to the first electrode 100R1 of the red micro-LED chip 100R. The fourth conductive pad 540 is electrically connected to the second electrode 100B2 of the blue micro-LED chip 100B, the second electrode 100G2 of the green micro-LED chip 100G, and the second electrode 100R2 of the red micro-LED chip 100R. In some embodiments, the number of conductive pads 500 may be four, five, six, or the like, but the present disclosure is not limited thereto, and the number of conductive pads 500 may be adjusted according to design requirements.

In some embodiments, the arrangement that the first electrode 100B1 of the blue micro-LED chip 100B, the first electrode 100G1 of the green micro-LED chip 100G, and the first electrode 100R1 of the red micro-LED chip 100R are electrically connected to the first conductive pad 510, the second conductive pad 520 and the third conductive pad 530 can be adjusted as needed. For example, the first electrode 100G1 of the green micro-LED chip 100G may be electrically connected to the first conductive pad 510, the first electrode 100B1 of the blue micro-LED chip 100B may be electrically connected to the second conductive pad 520, and the first electrode 100R1 of the red micro-LED chip 100R can be electrically connected to the third conductive pad 530.

In some embodiments, the first conductive junction 810, the second conductive junction 820, the third conductive junction 830, and the fourth conductive junction 840 are connected to routings (not shown) in the second substrate 900 to control the light emitting of the micro-LED package 1000.

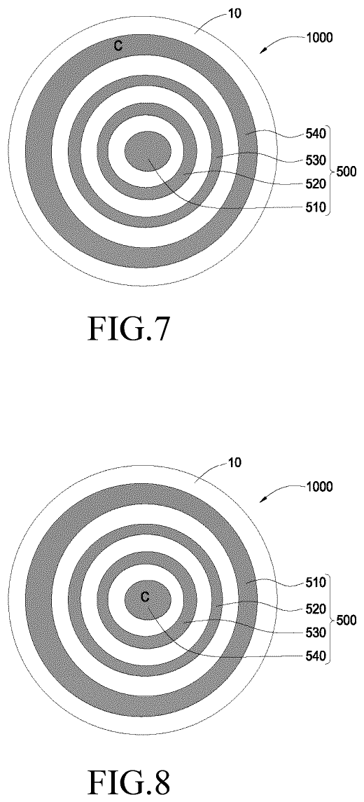

FIG. 7 is a bottom view of a micro-LED package according to some embodiments of the present disclosure. Referring to FIG. 7, the shape of the micro-LED package 1000 in a top view may be circular. In some embodiments, the first substrate 10 of the micro-LED package 1000 is circular, and the first conductive pad 510, the second conductive pad 520, the third conductive pad 530, and the fourth conductive pad 540 form a concentric circle structure on the first substrate 10. Through the circuit routings (not shown) in the first substrate 10, each of the first conductive pad 510, the second conductive pad 520, and the third conductive pad 530 is electrically connected to the first electrode 100F of the corresponding one of the micro-LED chips 100 respectively, and the fourth conductive pad 540 is electrically connected to each of the second electrode 100S of the plurality of the micro-LED chips 100.

In some embodiments, through the circuit routings (not shown) in the first substrate 10, the first conductive pad 510 is electrically connected to the first electrode 100G1 of the green micro-LED chip 100G, and the second conductive pad 520 is electrically connected to the first electrode 100B1 of the blue micro-LED chip 100B. The third conductive pad 530 is electrically connected to the first electrode 100R1 of the red micro-LED chip 100R. The fourth conductive pad 540 is electrically connected to the second electrode 100B2 of the blue micro-LED chip 100B, the second electrode 100G2 of the green micro-LED chip 100G, and the second electrode 100R2 of the red micro-LED chip 100R; that is, the fourth conductive pad 540 is a common electrode.

In some embodiments, the arrangement that the first electrode 100B1 of the blue micro-LED chip 100B, the first electrode 100G1 of the green micro-LED chip 100G, and the first electrode 100R1 of the red micro-LED chip 100R are electrically connected to the first conductive pad 510, the second conductive pad 520, and the third conductive pad 530 can be adjusted as needed. For example, the first electrode 100B1 of the blue micro-LED chip 100B may be electrically connected to the first conductive pad 510, the first electrode 100G1 of the green micro-LED chip 100G may be electrically connected to the second conductive pad 520, and the first electrode 100R1 of the red micro-LED chip 100R may be electrically connected to the third conductive pad 530.

Referring to FIG. 7, in some embodiments, the fourth conductive pad 540 surrounds the first conductive pad 510, the second conductive pad 520, and the third conductive pad 530 in a concentric circle shape; that is, the fourth conductive pad 540 is in the outermost region. That is, the common electrode is in the outermost region. In some embodiments, the first conductive pad 510 is circular, the second conductive pad 520 is annular, the third conductive pad 530 is annular, and the fourth conductive pad 540 is annular.

In some embodiments, the first conductive pad 510, the second conductive pad 520, the third conductive pad 530, and the fourth conductive pad 540 are spaced apart from each other. There are three spacings between the first conductive pad 510, the second conductive pad 520, the third conductive pad 530, and the fourth conductive pad 540. There is a spacing between the fourth conductive pad 540 and the edge of the first substrate 10.

Referring to FIG. 8, in some embodiments, the first conductive pad 510, the second conductive pad 520, and the third conductive pad 530 surround the fourth conductive pad 540 in a concentric circle shape; that is, the fourth conductive pad 540 is in the innermost region. That is, the common electrode is in the innermost region. In some embodiments, the fourth conductive pad 540 is circular, the third conductive pad 530 is annular, the second conductive pad 520 is annular, and the first conductive pad 510 is annular. In some embodiments, there are three spacings between the first conductive pad 510, the second conductive pad 520, the third conductive pad 530, and the fourth conductive pad 540. There is a spacing between the fourth conductive pad 510 and the edge of the first substrate 10.

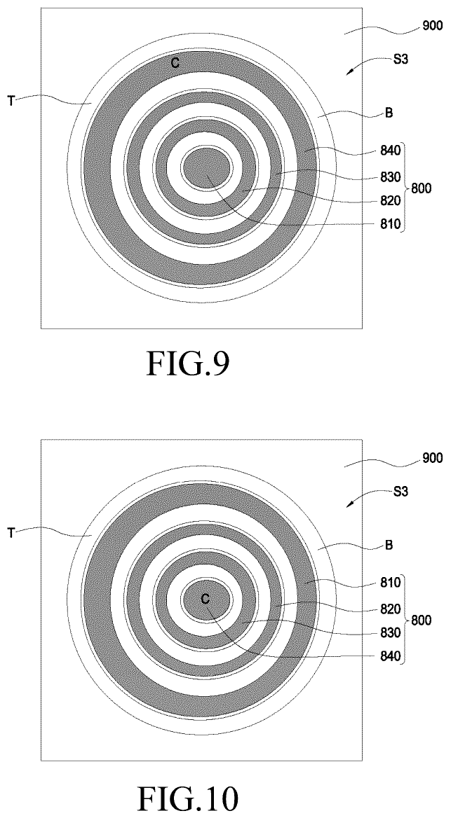

FIG. 9 is a top view of the second substrate 900 according to some embodiments of the present disclosure. Referring to FIG. 9, the accommodating groove T of the second substrate 900 is circular, the first conductive junction 810, the second conductive junction 820, the third conductive junction 830, and the fourth conductive junction 840 are concentric circle structures and are arranged on the bottom surface B in the accommodating groove T. In some embodiments, the fourth conductive junction 840 surrounds the first conductive junction 810, the second conductive junction 820, and the third conductive junction 830. That is, the fourth conductive junction 840 is in the outermost region.

Referring to FIG. 9, in some embodiments, the first conductive junction 810, the second conductive junction 820, the third conductive junction 830, and the fourth conductive junction 840 may be closed concentric circle structures. In some embodiments, the first conductive junction 810 is circular, the second conductive junction 820 is annular, the third conductive junction 830 is annular, and the fourth conductive junction 840 is annular.

In some embodiments, the first conductive junction 810, the second conductive junction 820, the third conductive junction 830, and the fourth conductive junction 840 are spaced apart from each other. In some embodiments, there are three spacings between the first conductive junction 810, the second conductive junction 820, the third conductive junction 830, and the fourth conductive junction 840. There is a spacing between the fourth conductive junction 840 and the edge of the accommodating groove T.

In some embodiments, the shape of the micro-LED package 1000 in plan view may be elliptical, circular, or other shapes, but the present disclosure is not limited thereto. In some embodiments, the shape of the accommodating groove T in plan view may be elliptical, circular, or other shapes, but the present disclosure is not limited thereto. In some embodiments, the accommodating groove T is substantially matched with the micro-LED package 1000 in shape.

FIG. 10 is a top view of the second substrate 900 according to some embodiments of the present disclosure. Referring to FIG. 10, in some embodiments, the accommodating groove T of the second substrate 900 is circular, and the first conductive junction 810, the second conductive junction 820, the third conductive junction 830, and the fourth conductive junction 840 are concentric circle structures and are arranged on the bottom surface B in the accommodating groove T. The first conductive junction 810, the second conductive junction 820, and the third conductive junction 830 surround the fourth conductive junction 840; that is, the fourth conductive junction 840 is in the innermost region.

In some embodiments, the first conductive junction 810, the second conductive junction 820, the third conductive junction 830, and the fourth conductive junction 840 are spaced apart from each other. In some embodiments, there are three spacings between the first conductive junction 810, the second conductive junction 820, the third conductive junction 830, and the fourth conductive junction 840. There is a spacing between the first conductive junction 810 and the edge of the accommodating groove T.

Referring to FIG. 10, in some embodiments, the first conductive junction 810, the second conductive junction 820, the third conductive junction 830, and the fourth conductive junction 840 may be closed concentric circle structures. In some embodiments, the fourth conductive junction 840 is circular, the third conductive junction 830 is annular, the second conductive junction 820 is annular, and the first conductive junction 810 is annular.

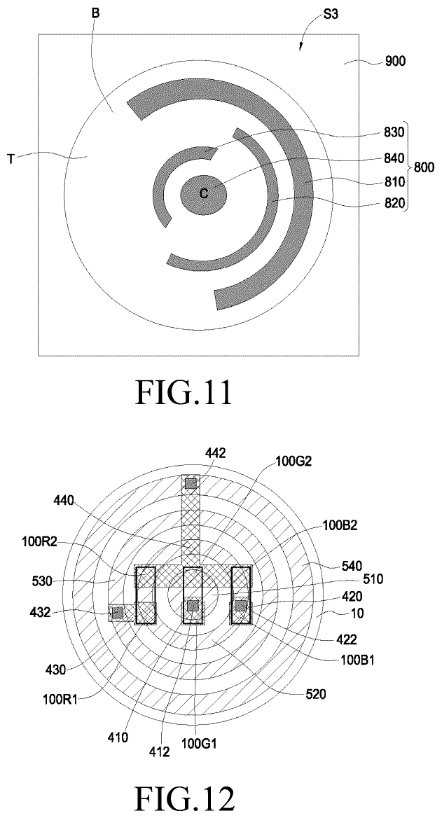

FIG. 11 is a top view of a second substrate according to some embodiments of the present disclosure. Referring to FIG. 11, in some embodiments, the accommodating groove T of the second substrate 900 is circular, and the first conductive junction 810, the second conductive junction 820, the third conductive junction 830, and the fourth conductive junction 840 are arranged on the bottom surface B in the accommodation groove T. The first conductive junction 810, the second conductive junction 820, the third conductive junction 830, and the fourth conductive junction 840 may be non-closed concentric arc structures. In some embodiments, the first conductive junction 810, the second conductive junction 820, and the third conductive junction 830 may be arc-shaped and the fourth conductive junction 840 may be circular. The first conductive junction 810, the second conductive junction 820, the third conductive junction 830, and the fourth conductive junction 840 are spaced apart from each other.

FIG. 12 is a schematic diagram of the circuit routings of the first substrate 10 of the micro-LED package 1000 according to some embodiments of the present disclosure. FIG. 12 is a schematic diagram of the circuit routings of the first substrate 10 of the micro-LED package 1000 in FIG. 7. In some embodiments, the shape of the micro-LED package 1000 may be circular in a top view. In some embodiments, the first substrate 10 of the micro-LED package 1000 is circular. The first electrode 100G1 of the green micro-LED chip 100G is electrically connected to the conductive circuit 410, and the conductive circuit 410 is electrically connected to the via 412, which passes through the first substrate 10 from the upper surface S1 of the first substrate 10 to the lower surface S2 and is electrically connected to the first conductive pad 510 on the lower surface S2. The first electrode 100B1 of the blue micro-LED chip 100B is electrically connected to the conductive circuit 420, and the conductive circuit 420 is electrically connected to the via 422, which passes through the first substrate 10 from the upper surface S1 of the first substrate 10 to the lower surface S2 and is electrically connected to the second conductive pad 520 on the lower surface S2. The first electrode 100R1 of the red micro-LED chip 100R is electrically connected to the conductive circuit 430, the conductive circuit 430 is electrically connected to the via 432, and the via 432 is connected to the third conductive pad 530 below it. Furthermore, the second electrode 100B2 of the blue micro-LED chip 100B, the second electrode 100G2 of the green micro-LED chip 100G, and the second electrode 100R2 of the red micro-LED chip 100R are electrically connected to the conductive circuit 440, and the conductive circuit 440 is electrically connected to the via 442, which passes through the first substrate 10 from the upper surface S1 of the first substrate 10 to the lower surface S2 and is electrically connected to the fourth conductive pad 540 on the lower surface S2.

In some embodiments, the conductive circuit 410, the conductive circuit 420, the conductive circuit 430, and the conductive circuit 440 are flatly arranged on the upper surface S1 of the first substrate 10. In some embodiments, the conductive circuit 430 is elongated in shape. In some embodiments, the conductive circuit 440 is T-shaped.

Through the structural design of the circuit routings described above, the first conductive pad 510 is electrically connected to the first electrode 100G1 of the green micro-LED chip 100G, and the second conductive pad 520 is electrically connected to the first electrode 100B1 of the blue micro-LED chip 100B. The third conductive pad 530 is electrically connected to the first electrode 100R1 of the red micro-LED chip 100R. The fourth conductive pad 540 is electrically connected to the second electrode 100B2 of the blue micro-LED chip 100B, the second electrode 100G2 of the green micro-LED chip 100G, and the second electrode 100R2 of the red micro-LED chip 100R.

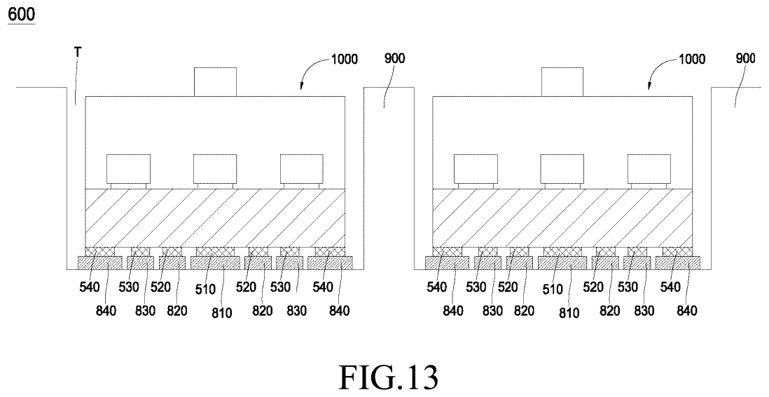

FIG. 13 is a schematic cross-sectional view of a micro-LED package mounted on a second substrate according to some embodiments of the present disclosure. Referring to FIG. 13, the micro-LED package 1000 is disposed in the accommodating groove T of the second substrate 900 by the fluid assembly. Because the first conductive pad 510, the second conductive pad 520, the third conductive pad 530, and the fourth conductive pad 540 are concentric circles, and the first conductive junction 810, the second conductive junction 820, the third conductive junction 830, and the fourth conductive junction 840 are concentric circles, during fluid assembly, as long as the first conductive pad 510, the second conductive pad 520, the third conductive pad 530 and the fourth conductive pad 540 face downward, the micro-LED package 1000 can ensure, at any angle within a 360-degree range in the horizontal direction, that each of the first conductive pad 510, the second conductive pad 520, the third conductive pad 530 and the fourth conductive pad 540 of the micro-LED package 1000 is connected to each of the first conductive junction 810, the second conductive junction 820, the third conductive junction 830 and the fourth conductive junction 840 in the correct direction and the correct polarity. In some embodiments, the shape of the micro-LED package 1000 may be circular in a top view. In some embodiments, each of the spacings between the first conductive junction 810, the second conductive junction 820, the third conductive junction 830, and the fourth conductive junction 840 corresponds to each of the spacings between the first conductive pad 510, the second conductive pad 520, the third conductive pad 530, and the fourth conductive pad 540.

Referring to FIG. 13, in some embodiments, the first conductive junction 810 is electrically connected to the first electrode 100G1 of the green micro-LED chip 100G through the first conductive pad 510. The second conductive junction 820 is electrically connected to the first electrode 100B1 of the blue micro-LED chip 100B through the second conductive pad 520. The third conductive junction 830 is electrically connected to the first electrode 100R1 of the red micro-LED chip 100R through the third conductive pad 530. The fourth conductive junction 840 is electrically connected to the second electrode 100B2 of the blue micro-LED chip 100B, the second electrode 100G2 of the green micro-LED chip 100G, and the second electrode 100R2 of the red micro-LED chip 100R through the fourth conductive pad 540. In some embodiments, a plurality of micro-LED packages are mounted to a plurality of accommodating grooves T of the second substrate 900 to form a micro-LED display device 600.

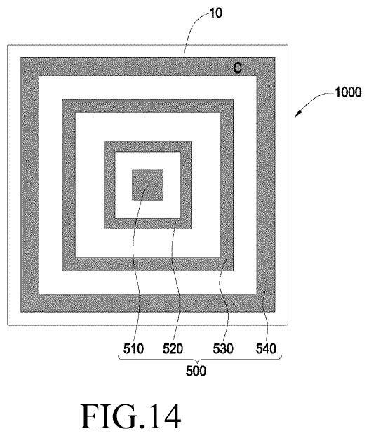

FIG. 14 is a bottom view of a micro-LED package according to some embodiments of the present disclosure. Referring to FIG. 14, in some embodiments, the shape of the micro-LED package 1000 in the top view may be rectangular. In some embodiments, the first substrate 10 of the rectangular micro-LED package 1000 is rectangular, and the first conductive pad 510, the second conductive pad 520, the third conductive pad 530, and the fourth conductive pad 540 form a concentric square structure on the first substrate 10. In some embodiments, the first conductive pad 510, the second conductive pad 520, the third conductive pad 530, and the fourth conductive pad 540 are spaced apart from each other. There are three spacings between the first conductive pad 510, the second conductive pad 520, the third conductive pad 530, and the fourth conductive pad 540. There is a spacing between the fourth conductive pad 540 and the edge of the first substrate 10.

Referring to FIG. 14, in some embodiments, the fourth conductive pad 540 surrounds the first conductive pad 510, the second conductive pad 520, and the third conductive pad 530 in a concentric square shape; that is, the fourth conductive pad 540 is in the outermost region. That is, the common electrode (the fourth conductive pad 540) is in the outermost region.

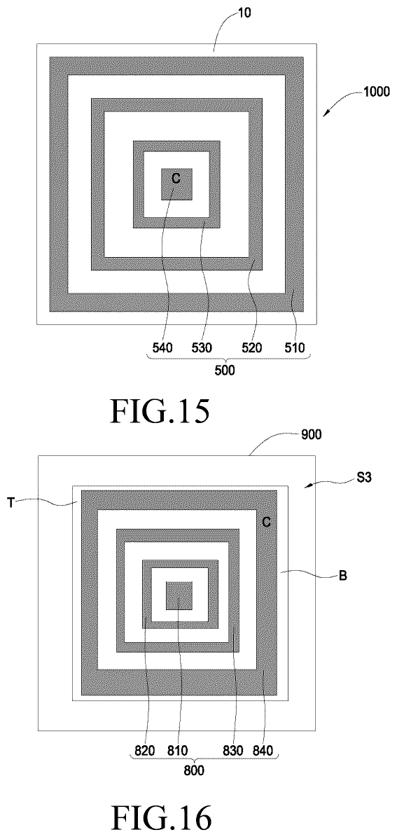

FIG. 15 is a bottom view of a micro-LED package according to some embodiments of the present disclosure. Referring to FIG. 15, in some embodiments, the shape of the micro-LED package 1000 in a top view may be rectangular. In some embodiments, the first substrate 10 of the micro-LED package 1000 is rectangular, and the first conductive pad 510, the second conductive pad 520, the third conductive pad 530, and the fourth conductive pad 540 form a concentric square structure on the first substrate 10. Referring to FIG. 15, in some embodiments, the first conductive pad 510, the second conductive pad 520, and the third conductive pad 530 surround the fourth conductive pad 540 in a concentric square shape; that is, the fourth conductive pad 540 is in the innermost region. That is, the common electrode (the fourth conductive pad 540) is in the innermost region. The first conductive pad 510, the second conductive pad 520, the third conductive pad 530, and the fourth conductive pad 540 are spaced apart from each other. There are three spacings between the first conductive pad 510, the second conductive pad 520, the third conductive pad 530, and the fourth conductive pad 540. There is a spacing between the first conductive pad 510 and the edge of the first substrate 10.

FIG. 16 is a top view of the second substrate according to some embodiments of the present disclosure. Referring to FIG. 16, the accommodating groove T of the second substrate 900 is rectangular, and the first conductive junction 810, the second conductive junction 820, the third conductive junction 830, and the fourth conductive junction 840 are concentric square structures and are arranged on the bottom surface B in the accommodation groove T. In some embodiments, the fourth conductive junction 840 surrounds the first conductive junction 810, the second conductive junction 820, and the third conductive junction 830 in a concentric square shape; that is, the fourth conductive junction 840 is in the outermost region. In some embodiments, the first conductive junction 810, the second conductive junction 820, the third conductive junction 830, and the fourth conductive junction 840 are spaced apart from each other. There are three spacings between the first conductive junction 810, the second conductive junction 820, the third conductive junction 830, and the fourth conductive junction 840. There is a spacing between the fourth conductive junction 840 and the edge of the accommodating groove T.

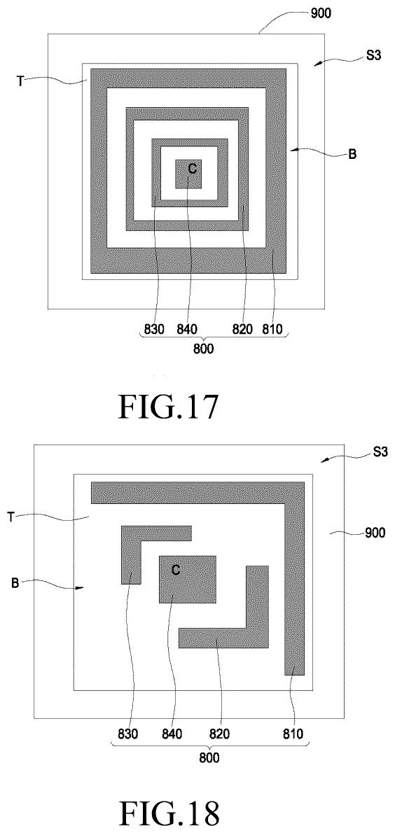

FIG. 17 is a top view of a second substrate according to some embodiments of the present disclosure. Referring to FIG. 17, in some embodiments, the first conductive junction 810, the second conductive junction 820, and the third conductive junction 830 surround the fourth conductive junction 840 in a concentric square shape; that is, the fourth conductive junction 840 is in the innermost region. The first conductive junction 810, the second conductive junction 820, the third conductive junction 830, and the fourth conductive junction 840 are spaced apart from each other. There are three spacings between the first conductive junction 810, the second conductive junction 820, the third conductive junction 830, and the fourth conductive junction 840. There is a spacing between the first conductive junction 810 and the edge of the accommodating groove T.

Referring to FIG. 16 or FIG. 17, in some embodiments, the first conductive junction 810, the second conductive junction 820, the third conductive junction 830, and the fourth conductive junction 840 may be closed concentric square structures.

Referring to FIG. 18, in some embodiments, the first conductive junction 810, the second conductive junction 820, the third conductive junction 830, and the fourth conductive junction 840 may be non-closed concentric square structures. In some embodiments, the first conductive junction 810, the second conductive junction 820, and the third conductive junction 830 are L-shaped.

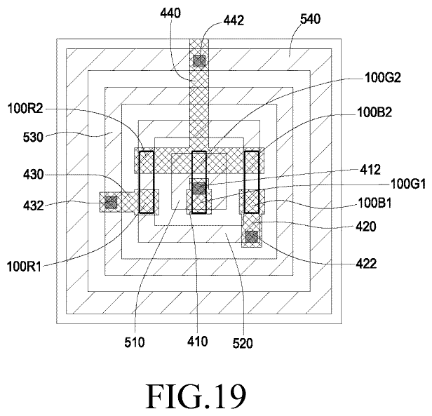

FIG. 19 is a schematic diagram of the circuit routings of the first substrate 10 of the micro-LED package 1000 according to some embodiments of the present disclosure. FIG. 19 is a schematic diagram of the circuit routings of the first substrate 10 of the micro-LED package 1000 in FIG. 14. The first electrode 100G1 of the green micro-LED chip 100G is electrically connected to the conductive circuit 410, and the conductive circuit 410 is electrically connected to the via 412, which passes through the first substrate 10 from the upper surface S1 of the first substrate 10 to the lower surface S2 and is electrically connected to the first conductive pad 510 on the lower surface S2. The first electrode 100B1 of the blue micro-LED chip 100B is electrically connected to the conductive circuit 420, and the conductive circuit 410 is electrically connected to the via 422, which passes through the first substrate 10 from the upper surface S1 of the first substrate 10 to the lower surface S2 and is electrically connected to the second conductive pad 520 on the lower surface S2. The first electrode 100R1 of the red micro-LED chip 100R is electrically connected to the conductive circuit 430, and the conductive circuit 430 is electrically connected to the via 432, which passes through the first substrate 10 from the upper surface S1 of the first substrate 10 to the lower surface S2 and is electrically connected to the third conductive pad 530 on the lower surface S2. Furthermore, the second electrode 100B2 of the blue micro-LED chip 100B, the second electrode 100G2 of the green micro-LED chip 100G, and the second electrode 100R2 of the red micro-LED chip 100R are electrically connected to the conductive circuit 440, and the conductive circuit 440 is electrically connected to the via 442, which passes through the first substrate 10 from the upper surface S1 of the first substrate 10 to the lower surface S2 and is electrically connected to the fourth conductive pad 540 on the lower surface S2.

In some embodiments, the conductive circuit 410, the conductive circuit 420, the conductive circuit 430, and the conductive circuit 440 are flatly arranged on the upper surface S1 of the first substrate 10. The conductive circuit 420 and the conductive circuit 430 are elongated in shape. In some embodiments, conductive circuit 440 is T-shaped.

Through the structural design of the circuit routings described above, the first conductive pad 510 is electrically connected to the first electrode 100G1 of the green micro-LED chip 100G, and the second conductive pad 520 is electrically connected to the first electrode 100B1 of the blue micro-LED chip 100B. The third conductive pad 530 is electrically connected to the first electrode 100R1 of the red micro-LED chip 100R. The fourth conductive pad 540 is electrically connected to the second electrode 100B2 of the blue micro-LED chip 100B, the second electrode 100G2 of the green micro-LED chip 100G, and the second electrode 100R2 of the red micro-LED chip 100R.

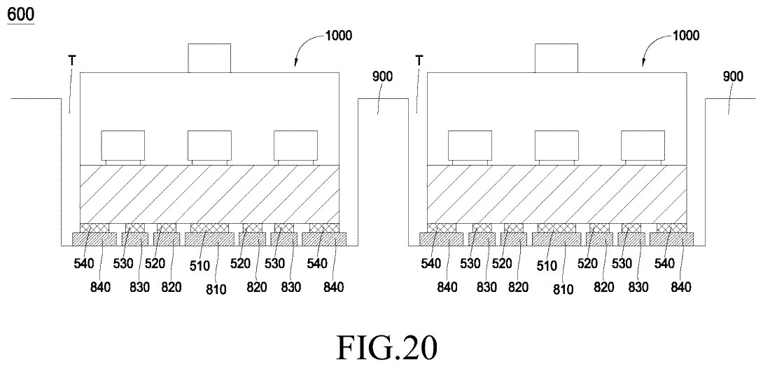

FIG. 20 is a schematic cross-sectional view of a micro-LED package mounted on a second substrate according to some embodiments of the present disclosure. Referring to FIG. 20, in some embodiments, the micro-LED package 1000 is disposed in the accommodating groove T of the second substrate 900 through the fluid assembly. Because the first conductive pad 510, the second conductive pad 520, the third conductive pad 530, and the fourth conductive pad 540 are concentric squares, and the first conductive junction 810, the second conductive junction 820, the third conductive junction 830, and the fourth conductive junction 840 are concentric squares, when the micro-LED package 1000 is in fluid assembly, as long as the first conductive pad 510, the second conductive pad 520, the third conductive pad 530 and the fourth conductive pad 540 face downward, it can be ensured that the first conductive pad 510, the second conductive pad 520, the third conductive pad 530 and the fourth conductive pad 540 of the micro-LED package 1000 are connected to the first conductive junction 810, the second conductive junction 820, the third conductive junction 830, and the fourth conductive junction 840 in the correct direction and the correct polarity each time when the micro-LED package 1000 rotates 90 degrees in the horizontal direction.

FIG. 20 is a schematic cross-sectional view of a micro-LED package mounted on a second substrate according to some embodiments of the present disclosure. Referring to FIG. 20, in some embodiments, the first conductive junction 810 is electrically connected to the first electrode 100G1 of the green micro-LED chip 100G through the first conductive pad 510. The second conductive junction 820 is electrically connected to the first electrode 100B1 of the blue micro-LED chip 100B through the second conductive pad 520. The third conductive junction 830 is electrically connected to the first electrode 100R1 of the red micro-LED chip 100R through the third conductive pad 530. The fourth conductive junction 840 is electrically connected to the second electrode 100B2 of the blue micro-LED chip 100B, the second electrode 100G2 of the green micro-LED chip 100G, and the second electrode 100R2 of the red micro-LED chip 100R through the fourth conductive pad 540. In some embodiments, a plurality of micro-LED packages are mounted to a plurality of accommodating groove T of the second substrate 900 to form a micro-LED display device 600.

FIG. 21 is a bottom view of a micro-LED package according to some embodiments of the present disclosure. In some embodiments, the shape of the micro-LED package 1000 may be rectangular in a top view. In some embodiments, the first substrate 10 is rectangular, a first conductive pad 510 is disposed at the center point of the first substrate 10, a second conductive pad 520 corresponds to the relative middle position of any one of the four sides of the lower surface S2 of the first substrate 10, a third conductive pad 530 is disposed at the relative vertex position of the rectangular diagonal line of the lower surface S2 of the first substrate 10. The fourth conductive pad 540 surrounds the first conductive pad 510, the second conductive pad 520, and the third conductive pad 530. In some embodiments, the fourth conductive pad 540 is a common electrode.

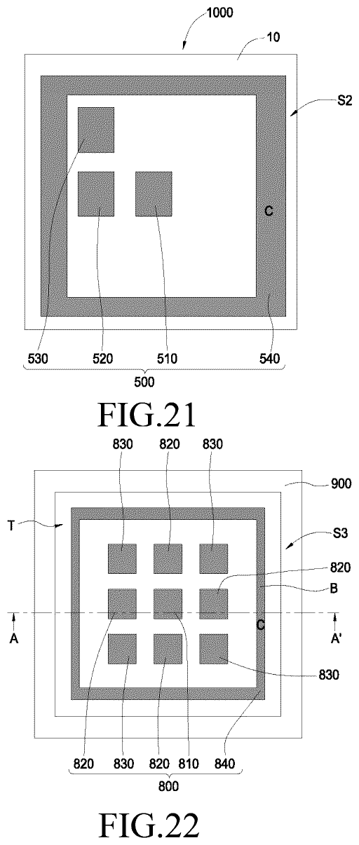

FIG. 22 is a top view of the second substrate 900 according to some embodiments of the present disclosure. Referring to FIG. 22, in some embodiments, the accommodating groove T of the second substrate 900 is rectangular, the first conductive junction 810 is disposed at the center point of the bottom surface B of the second substrate 900, four second conductive junctions 820 are disposed at relatively middle positions on the four sides of the bottom surface B of the second substrate 900, and the four third conductive junctions 830 are disposed at the relative vertex positions of the rectangular diagonals on the bottom surface B of the second substrate 900. The fourth conductive junction 840 surrounds the first conductive junction 810, the second conductive junction 820, and the third conductive junction 830.

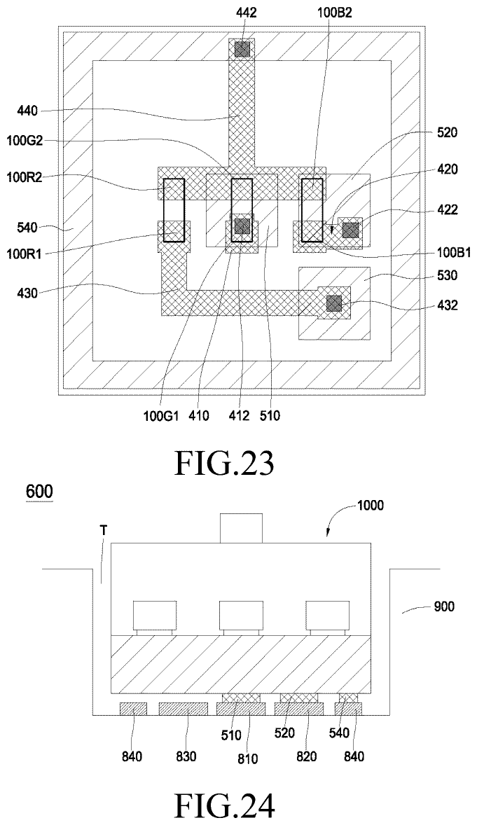

FIG. 23 is a schematic diagram of the circuit routings of the first substrate 10 of the micro-LED package 1000 according to some embodiments of the present disclosure. FIG. 23 is a schematic diagram of the circuit routings of the first substrate 10 of the micro-LED package 1000 in FIG. 21. The first electrode 100G1 of the green micro-LED chip 100G is electrically connected to the conductive circuit 410, and the conductive circuit 410 is electrically connected to the via 412, which passes through the first substrate 10 from the upper surface S1 of the first substrate 10 to the lower surface S2 and is electrically connected to the first conductive pad 510 on the lower surface S2. The first electrode 100B1 of the blue micro-LED chip 100B is electrically connected to the conductive circuit 420, and the conductive circuit 420 is electrically connected to the via 422, which passes through the first substrate 10 from the upper surface S1 of the first substrate 10 to the lower surface S2 and is electrically connected to the second conductive pad 520 on the lower surface S2. The first electrode 100R1 of the red micro-LED chip 100R is electrically connected to the conductive circuit 430, and the conductive circuit 430 is electrically connected to the via 432, which passes through the first substrate 10 from the upper surface S1 of the first substrate 10 to the lower surface S2 and is electrically connected to the third conductive pad 530 on the lower surface S2. Furthermore, the second electrode 100B2 of the blue micro-LED chip 100B, the second electrode 100G2 of the green micro-LED chip 100G, and the second electrode 100R2 of the red micro-LED chip 100R are electrically connected to the conductive circuit 440, and the conductive circuit 440 is electrically connected to the via 442, which passes through the first substrate 10 from the upper surface S1 of the first substrate 10 to the lower surface S2 and is electrically connected to the fourth conductive pad 540 on the lower surface S2.

In some embodiments, the conductive circuit 420 may be in an elongated shape. In some embodiments, the conductive circuit 430 may be in an L-shape. In some embodiments, the conductive circuit 440 may be in a T-shape.

Through the structural design of the circuit routings described above, the first conductive pad 510 is electrically connected to the first electrode 100G1 of the green micro-LED chip 100G, and the second conductive pad 520 is electrically connected to the first electrode 100B1 of the blue micro-LED chip 100B. The third conductive pad 530 is electrically connected to the first electrode 100R1 of the red micro-LED chip 100R. The fourth conductive pad 540 is electrically connected to the second electrode 100B2 of the blue micro-LED chip 100B, the second electrode 100G2 of the green micro-LED chip 100G, and the second electrode 100R2 of the red micro-LED chip 100R.

FIG. 24 is a schematic cross-sectional view of the micro-LED package 1000 mounted on the second substrate 900 taken along line A-A′ in FIG. 22. Referring to FIG. 24, in some embodiments, a micro-LED package 1000 with a nine-grid conductive pad design is disposed in the accommodating groove T of the second substrate 900 through the fluid assembly. Because the first conductive pad 510, the second conductive pad 520, the third conductive pad 530, and the fourth conductive pad 540 are in a nine-square grid symmetrical design, and the first conductive junction 810, the second conductive junction 820, the third conductive junction 830, and the fourth conductive junction 840 are in a nine-square grid symmetrical design, as long as the first conductive pad 510, the second conductive pad 520, the third conductive pad 530, and the fourth conductive pad 540 face downward when the micro-LED package 1000 is in fluid assembly, it can be ensured that the first conductive pad 510, the second conductive pad 520, the third conductive pad 530, and the fourth conductive pad 540 of the micro-LED package 1000 are connected to the first conductive junction 810, the second conductive junction 820, the third conductive junction 830, and the fourth conductive junction 840 in the correct direction and the correct polarity each time when the micro-LED package 1000 rotates 90 degrees in the horizontal direction.

Referring to FIG. 24, in some embodiments, the micro-LED package 1000 with a nine-grid conductive pad design is disposed in the accommodating groove T of the second substrate 900, and the first conductive junction 810 is electrically connected to the first electrode 100G1 of the green micro-LED chip 100G through the first conductive pad 510. The second conductive junction 820 is electrically connected to the first electrode 100B1 of the blue micro-LED chip 100B through the second conductive pad 520. The third conductive junction 830 is electrically connected to the first electrode 100R1 of the red micro-LED chip 100R through the third conductive pad 530. The fourth conductive junction 840 is electrically connected to the second electrode 100B2 of the blue micro-LED chip 100B, the second electrode 100G2 of the green micro-LED chip 100G, and the second electrode 100R2 of the red micro-LED chip 100R through the fourth conductive pad 540. In some embodiments, a plurality of micro-LED packages 1000 are mounted to a plurality of accommodating groove T of the second substrate 900 to form a micro-LED display device 600.

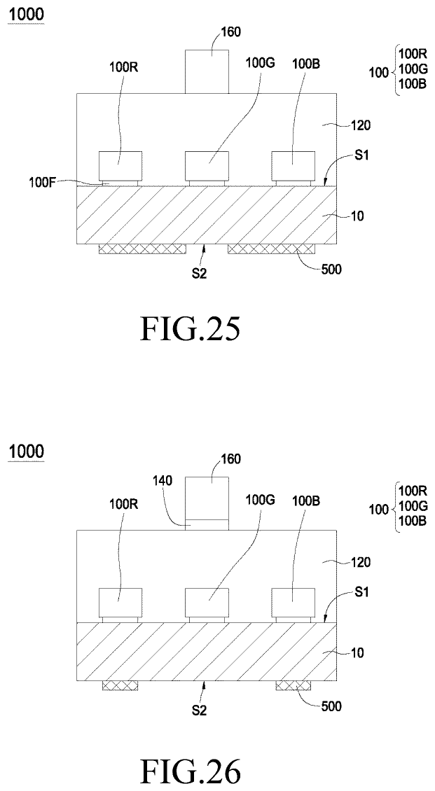

FIG. 25 is a schematic cross-sectional view of a micro-LED package according to some embodiments of the present disclosure. Referring to FIG. 25, in some embodiments, the micro-LED package 1000 includes a fluid-orienting pillar 160. The fluid-orienting pillar 160 is disposed on the transparent protective layer 120. The fluid-orienting pillar 160 can increase the possibility that the micro-LED package will be driven and flipped when it is suspended in the fluid until it falls into the accommodating groove T. In some embodiments, after disposing the micro-LED package 1000 in the accommodating groove T, the fluid-orienting pillar 160 can be removed. In some embodiments, micro-LED package 1000 does not include fluid-orienting pillar 160.

FIG. 26 is a schematic cross-sectional view of a micro-LED package according to some embodiments of the present disclosure. Referring to FIG. 26, in some embodiments, the micro-LED package 1000 further includes an adhesive layer 140, and the adhesive layer 140 is disposed between the fluid-orienting pillar 160 and the transparent protective layer 120. The adhesive layer 140 can make the fluid-orienting pillar 160 easier to adhere to the transparent protective layer 120. The adhesive layer 140 may be silicon dioxide, but the present disclosure is not limited thereto. In some embodiments, the adhesive layer 140 may be wet etched to remove the fluid-orienting pillar 160. In some embodiments, after disposing the micro-LED package 1000 in the accommodating groove T, the fluid-orienting pillar 160 can be removed. In some embodiments, micro-LED package 1000 does not include fluid-orienting pillar 160.

The present disclosure provides a method of manufacturing a micro-LED display device 600. The method includes: (A) providing a second substrate 900, wherein the second substrate 900 has a plurality of accommodating grooves T, and the first conductive junctions 810, the second conductive junctions 820, the third conductive junctions 830, and the fourth conductive junctions 840 are disposed on the bottom surfaces B of the accommodating grooves T. The method further includes: (B) flowing the suspension fluid containing the micro-LED packages 1000 through the upper surface S3 of the second substrate 900. Since the micro-LED packages 1000 have the fluid-orienting pillars 160, when the fluid-orienting pillars 160 contact the upper surface S3 of the second substrate 900, it will flip over the second substrate 900 due to the flow of suspended fluid until it falls into the accommodating grooves T. The method further includes: (C) disposing micro-LED packages 1000 in the accommodating grooves T.

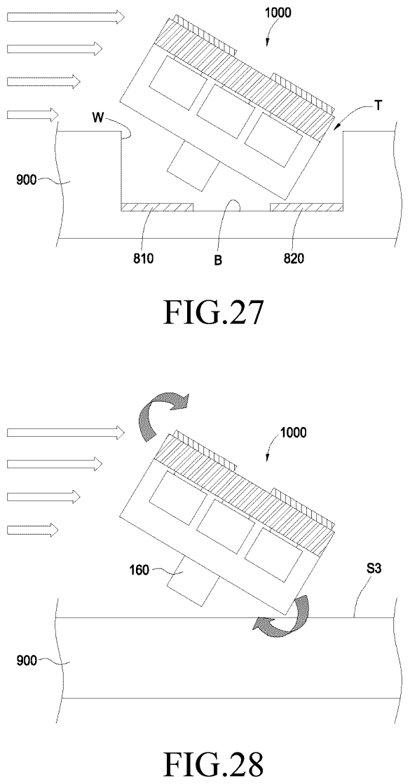

FIG. 27 shows the situation of micro-LED packages in fluid assembly according to some embodiments of the present disclosure. Referring to FIG. 27, when the micro-LED package 1000 falls into the accommodating groove T, the first conductive pad 510, the second conductive pad 520, the third conductive pad 530, and the fourth conductive pad 540 of the micro-LED package 1000 do not face the accommodating groove T, so the micro-LED package 1000 is not able to be disposed in the accommodating groove T. Instead, the micro-LED package 1000 will be driven by the suspended fluid, leave the accommodating groove T, and continue to roll on the second substrate 900 until it falls into another accommodating groove T.

FIG. 28 shows the situation of the micro-LED package in fluid assembly according to some embodiments of the present disclosure. When the fluid-orienting pillar 160 of the micro-LED package 1000 contacts the upper surface S3 of the second substrate 900 during the fluid assembly process, the micro-LED package 1000 will flip over on the second substrate 900 until it falls into the accommodating groove T due to the fluid-orienting pillar 160 and the flow of the suspension fluid.

The micro-LED package 1000 of the present disclosure is mounted on the accommodating groove T of the second substrate 900 by a fluid assembly method in a fluid, thereby forming a micro-LED display device 600. In some embodiments, during the fluid assembly process, the transparent protective layer 120 covers the micro-LED package 1000 so that the micro-LED chip 100 does not contact the fluid, and thus the transparent protective layer 120 can protect the micro-LED chip 100. In some embodiments, during the fluid assembly process, it can avoid damage to the micro-LED chip 100 due to collision during fluid flow. After the micro-LED package 1000 is mounted, the fluid-orienting pillar 160 is removed from the transparent protective layer 120.

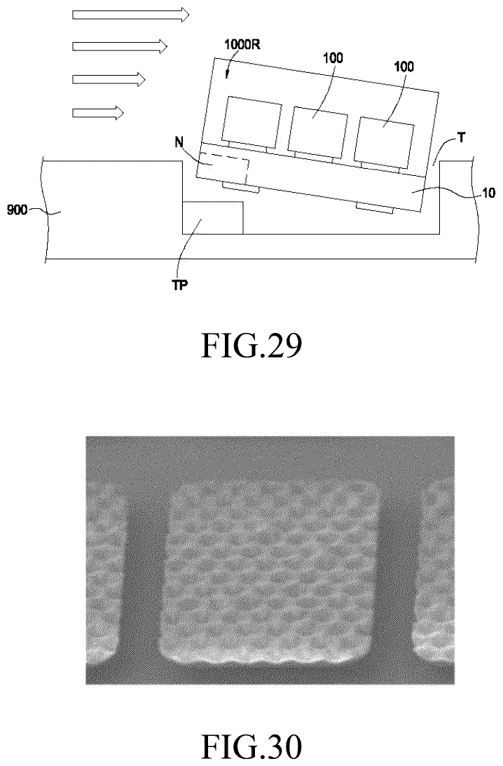

FIG. 29 shows the situation of the micro-LED package during fluid assembly of Comparative Embodiment 1 of the present disclosure. Comparative Embodiment 1 is a tenon structure design. Comparative Embodiment 1 is a micro-LED package 1000R, which includes a first substrate 10, a plurality of micro-LED chips 100, a packaging layer, and a plurality of conductive pads. The first substrate 10 has an upper surface and a lower surface, and the edge of the lower surface has a notch N. A plurality of micro-LED chips 100 are disposed on the upper surface of the first substrate 10. A plurality of conductive pads are disposed on the lower surface of the first substrate 10 and are electrically connected to the positive electrode and the negative electrodes of the micro-LED chips 100, respectively. The second substrate 900 has an accommodating groove T and a protruding portion TP. The conductive junctions are disposed on the bottom surface of the accommodating groove T. When the protruding portion TP of the second substrate 900 is located in the notch N of the first substrate of the micro-LED package 1000R, the micro-LED package 1000R is correctly positioned in the accommodating groove T. However, due to the square design of the protruding portion TP, during fluid assembly, there is only a small angular range in the horizontal direction to align the protruding portion TP with the notch N of the first substrate, and thus the protruding portion TP of the second substrate 900 is often not aligned with the notch N of the first substrate 110, making it difficult for the protruding portion TP to enter the notch N. Therefore, the micro-LED package 1000R is not able to be disposed in the accommodating groove T, which reduces the manufacturing speed and manufacturing yield.

Referring to FIG. 4, in some embodiments of the present disclosure, the micro-LED package 1000 has a silicon wafer-like flat-cut edge P design, and because the presence of the single flat-cut edge P tolerates a larger horizontal angle range, the single flat-cut edge P design makes it easier to align the flat edge protrusion TP of the second substrate 900, and can be used to increase manufacturing speed and manufacturing yield. Referring to FIG. 13, FIG. 20, and FIG. 24, the conductive pads 500 of concentric circles, the conductive pads 500 of concentric square design, and the conductive pads 500 of the symmetrical design of a nine-square grid can improve the efficiency of fluid assembly without additional tenon structure design.

In some embodiments, the light-emitting surface of the blue micro-LED chip 100B, the light-emitting surface of the green micro-LED chip 100G, and the light-emitting surface of the red micro-LED chip 100R have patterns. Referring to FIG. 30, FIG. 30 is a photo of the upper surface (light-emitting surface) of the blue micro-LED chip 100B and the green micro-LED chip 100G having periodically arranged concave and convex patterns. In some embodiments, the micro-LED chip 200 is not equipped with a sapphire substrate but is equipped with periodically arranged concave and convex patterns to enhance light extraction and adjust the pointing angle of the micro-LED chip 200 after laser light peels off the sapphire substrate. In some embodiments, the light-emitting surface of the red micro-LED chip 100R has uneven patterns.

In some embodiments, the micro-LED package 1000 may include control components disposed on the first substrate 10, where the control components include micro-drive integrated circuit devices, micro-control integrated circuit devices, or a combination thereof. The control components are electrically connected to the blue micro-LED chip 100B, the green micro-LED chip 100G, and the red micro-LED chip 100R to control the luminescence of the blue micro-LED chip 100B, the green micro-LED chip 100G, and the red micro-LED chip 100R.

In some embodiments, the shape of the micro-LED package 1000 in a top view may be rectangular. In some embodiments, the shape of the micro-LED package 1000 in a top view may be a polygon, such as a heptagon, a hexagon, a pentagon, a quadrilateral, or a triangle, but the disclosure is not limited thereto. In some embodiments, the shape of the accommodating groove T in a top view may be polygonal. In some embodiments, the shape of the accommodating groove T in a top view may be a heptagon, a hexagon, a pentagon, a quadrilateral, or a triangle, but the present disclosure is not limited thereto. In some embodiments, the accommodating groove T is substantially matched with the micro-LED package 1000 in shape.

When manufacturing a display, a plurality of micro-LED packages 1000 including micro-LED chips 100 of three different colors can be transferred into the accommodating groove T of the second substrate 900 at one time by the above-mentioned fluid assembly method. Since the micro-LED package 1000 is a pixel unit, only one transfer is required using the fluid assembly method of the present disclosure. Therefore, the structural design of the micro-LED package 1000 disclosed in the present disclosure can reduce manufacturing costs and significantly save manufacturing time. The present disclosure can be used to produce micro-LED displays with high pixel density (pixels per inch, PPI).

The flat-cut edge P of the micro-LED packages 1000 and the concentric circle, concentric square, and nine-square grid design of the conductive pad 500 disclosed in the present disclosure ensure that the conductive pad 500 and the conductive junction 800 of the micro-LED package 1000 are connected in the correct direction and polarity, thereby improving the yield of manufacturing the micro-LED display. The method of manufacturing a micro-LED display disclosed herein adopts a fluid assembly method, which can realize large-scale transfer of micro-LED packages 1000 to the second substrate 900, saving manufacturing time and significantly reducing manufacturing costs.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of the present disclosure, and that they can make various changes, substitutions, and replacements without violating the spirit and scope of the present disclosure. Therefore, the scope of protection of the present disclosure is defined by the scope of the claim attached hereto. In addition, although several preferred embodiments are disclosed in the present disclosure, they are not intended to limit the present disclosure.

What is claimed is:

1. A micro light-emitting diode (micro-LED) package, comprising:
a first substrate having an upper surface and a lower surface opposite to each other;
a plurality of micro-LED chips disposed on the upper surface of the first substrate, wherein each of the micro-LED chips has a first electrode and a second electrode electrically opposite to the first electrode;
a transparent protective layer covering the micro-LED chips; and
a plurality of conductive pads disposed on the lower surface of the first substrate, wherein
the conductive pads comprise a first conductive pad, a second conductive pad, a third conductive pad, and a fourth conductive pad, wherein each of the first conductive pad, the second conductive pad, and the third conductive pad is electrically connected to the first electrode of a corresponding one of the micro-LED chips respectively, and the fourth conductive pad is electrically connected to each of the second electrode of the micro-LED chips.

2. The micro light-emitting diode package as claimed in claim 1, wherein the first substrate is in a shape of a silicon wafer, and the first substrate has a flat edge.

3. The micro light-emitting diode package as claimed in claim 1, wherein the first substrate is circular, and the first conductive pad, the second conductive pad, the third conductive pad, and the fourth conductive pad form a concentric circle structure.

4. The micro light-emitting diode package as claimed in claim 3, wherein the fourth conductive pad surrounds the first conductive pad, the second conductive pad, and the third conductive pad.

5. The micro light-emitting diode package as claimed in claim 3, wherein the first conductive pad, the second conductive pad, and the third conductive pad surround the fourth conductive pad.

6. The micro light-emitting diode package as claimed in claim 1, wherein the first substrate is rectangular, and the first conductive pad, the second conductive pad, the third conductive pad, and the fourth conductive pad form a concentric square structure.

7. The micro light-emitting diode package as claimed in claim 6, wherein the fourth conductive pad surrounds the first conductive pad, the second conductive pad, and the third conductive pad.

8. The micro light-emitting diode package as claimed in claim 6, wherein the first conductive pad, the second conductive pad, and the third conductive pad surround the fourth conductive pad.

9. The micro light-emitting diode package as claimed in claim 1, wherein the first substrate is rectangular, the first conductive pad is disposed at a center point of the first substrate, the second conductive pad corresponds to a relative middle position of any one of four sides of the lower surface of the first substrate, the third conductive pad is disposed at a relative vertex position of a rectangular diagonal line of the lower surface of the first substrate.

10. The micro light-emitting diode package as claimed in claim 9, wherein the fourth conductive pad surrounds the first conductive pad, the second conductive pad, and the third conductive pad.
